(19) United States
(12) Patent Application Publication
(10) Pub. No.: US 2022/0403519 A1
(43) Pub. Date: Dec. 22, 2022

(54) METHOD FOR DEPOSITING A TWO-DIMENSIONAL COATING AND CVD REACTOR

(71) Applicant: AIXTRON SE, Herzogenrath (DE)

(72) Inventors: Kenneth B. K. TEO, Cambridge (GB); Clifford MCALEESE, Cambridge (GB); Ben Richard CONRAN, Cambridge (GB)

(21) Appl. No.: 17/773,523

(22) PCT Filed: Oct. 30, 2020
(86) PCT No.: PCT/EP2020/080509

§ 371 Date: Apr. 29, 2022

(30) Foreign Application Priority Data
Nov. 5, 2019 (DE) 10 2019 129 789.3

(51) Int. Cl. C23C 16/455; C23C 16/46; C23C 16/30

(52) U.S. Cl. CPC C23C 16/45574; C23C 16/46; C23C 16/305; C23C 16/45565; C23C 16/45561

(57) ABSTRACT

A coating is deposited on a substrate in a CVD reactor that includes a process chamber and a gas inlet member with a first gas distribution chamber and a second gas distribution chamber separate from the first gas distribution chamber. To deposit heterostructures, in a first step, an inert or a diluent gas is fed into the first gas distribution chamber and a reactive gas containing the elements of a first coating is fed into the second gas distribution chamber. The reactive gas pyrolytically decomposes in the process chamber to form the first coating on the substrate. In a second step, a diluent gas is fed into the second gas distribution chamber and a reactive gas containing the elements of a second coating is fed into the first gas distribution chamber. The reactive gas or gas mixture decomposes in the process chamber to form the second coating on the substrate.

### TECHNICAL AREA

The invention relates to a method for depositing a two-dimensional coating on a substrate in a CVD reactor, in which a process gas is fed via a supply line into a gas distribution chamber of a gas inlet member, which has gas outlet openings that open into a process chamber, in which in the process chamber the process gas or decomposition products of the process gas are brought into contact with a surface of a substrate, and in which the substrate is brought to a process temperature by means of a heating device, so that the process gas in the process chamber reacts chemically in such manner that the two-dimensional coating is deposited on the surface.

The invention further relates to an apparatus for depositing a two-dimensional coating on a substrate, with a CVD reactor, which has a gas inlet member with a supply line that opens into a gas distribution chamber, a process chamber, into which gas outlet openings of the gas distribution chambers open, and a susceptor which may be heated by a heating device and holds the substrate, wherein the supply line is connected to a gas mixing system, in which at least one inert gas from an inert gas source or a diluent gas from a diluent gas source and a reactive gas from at least one reactive gas source are provided, wherein the reactive gas has the capability when introduced into a heated process chamber to react chemically in such manner that a two-dimensional coating is deposited on the substrate.

The invention further relates to the use of a CVD reactor for depositing a two-dimensional coating on a substrate.

### RELATED ART

DE 10 2013 111 791 A1 describes the deposition of two-dimensional coatings using a CVD reactor, in which the gas inlet member is a showerhead. The deposition of graphene with a CVD reactor in which a showerhead is used as a gas inlet member, is known from WO 2017/029470 A1. CVD reactors are known from DE 10 2011 056 589 A1, DE 10 2010 016 471 A1 and DE 10 2004 007 984 A1, DE 10 2009 043 840 A1, DE 11 2004 001 026 T5, EP 1 255 876 B1, DE 10 2005 055 468 A1, 10 US 2006/0191637 A1, DE 10 2011 002 145 A1.

WO 2014/066100 A1 describes a showerhead having a gas outlet area which includes two gas outlet zones.

US 2010/119727 describes a showerhead having a multiple gas distribution chambers arranged one on top of the other.

### SUMMARY OF THE INVENTION

The object underlying the invention is to describe a CVD reactor with which several different two-dimensional coatings may be deposited adjacently, on top of each other or side by side, and to describe a related method.

This object is solved by the invention defined in the claims, wherein the subordinate claims not only represent advantageous further developments, but also stand-alone solutions to the object.

A CVD reactor according to the invention includes two volumes which are separate from each and each form a gas distribution chamber. A first process gas may be fed into a first gas distribution chamber. The process gas may be a gas mixture of several reactive gases, for example two reactive gases. The process gas may preferably be only one reactive gas. This first reactive gas may be used for depositing a first two-dimensional coating. The second gas distribution chamber is designed such that a second process gas may be fed into it, in order to deposit a second two-dimensional coating therewith. The second process gas is different from the first process gas and may consist of one or more reactive gases. However, the second process gas may preferably consist of only one reactive gas. When depositing multilayer structures, one process gas is fed into the one gas distribution chamber and a different process gas, is fed into the respective other gas distribution chamber one after the other, wherein each process gas is in particular one reactive gas or also a mixture of several, in particular two reactive gases. Preferably, a process gas is fed into only one of the several gas distribution chambers at any one time. The gas that is fed into the other of the several gas distribution chambers in each case is a diluent gas, which may be an inert gas, for example a noble gas such as argon, or may be a reducing gas such as hydrogen. In the method according to the invention, the gas inlet member includes at least two gas distribution chamber which are separate from each other. And which are each fed with different gases or gas mixtures via an individual supply line. However, the apparatus may also include more than two gas distribution chamber, each of which may be fed separately with a supply line. The gases exit simultaneously from different gas outlet openings, each of which is assigned to one of the gas distribution chambers. A CVD reactor according to the invention may include gas distribution chambers that are arranged vertically one above the other, wherein each may extend over the entire gas outlet surface of the gas inlet member. The gas outlet surface may have the form of a circular disc and have gas outlet openings arranged evenly thereon. The gas outlet openings are connected to the various gas distribution chambers, wherein each opening is only in fluid connection with one gas distribution chamber. The process gas may flow through the gas outlet openings into the process chamber of the CVD reactor, where it reacts chemically in such manner that a two-dimensional coating is deposited on the surface of a substrate, which may be a sapphire substrate, a silicon substrate or similar. Each gas distribution chamber is in fluid connection with the gas outlet area via a multiplicity of gas outlet openings, wherein the gas outlet openings are arranged substantially evenly over the gas outlet area. According to first variant of the invention, an inert gas or diluent gas is fed into a first of the gas distribution chambers, and a reactive gas is fed into a second of the gas distribution chamber, which reactive gas is decomposed either pyrolytically or otherwise, in particular by the introduction of energy in the process chamber, wherein the decomposition products form a two-dimensional coating on the substrate. In a second alternative of the invention, a different reactive gas may be fed into each of the gas distribution chambers. In the process chamber, the reactive gases may react with each other chemically to form a two-dimensional coating. In the first alternative, preferably graphene or hBN is deposited, wherein methane or borazine serves as the reactive gas. In the second alternative of the method, a gas of a transition metal, for example tungsten, molybdenum or similar, may be fed into one of the gas distribution chamber. Gas of the sixth main group, for example sulfur, selenium or tellurium may be fed into the second gas distribution chamber. The two-dimensional coatings may be transition metal chalcogenides. In a preferred variant, the CVD reactor has a gas outlet plate facing towards the process chamber, the rear side of which adjoins a cooling chamber, through which a cooling medium may flow. A first gas distribution chamber, into which a first gas is fed, may be located above the cooling chamber. The gas distribution chamber is connected to the gas outlet area of the gas outlet plate of the gas inlet member via pipes which cross the cooling chamber. First pipes alternate laterally with second pipes, wherein the first pipes connect the first gas distribution chamber to the gas outlet area, and the second pipes cross both the cooling chamber and the first gas distribution chamber and connect a second gas distribution chamber located above the first gas distribution chamber to the gas outlet area. On the other hand, the gas outlet member may also have a configuration such as is described in DE 10 2013 101 534 A1, DE 10 2009 043 840 A1 or DE 10 2007 026 349 A1. The contents of these documents are therefore incorporated in their entirety in the disclosure content of this filing. The base of the process chamber is formed by a susceptor, which may be heated to a process temperature of preferably more than 1000° C. by a heating device. According to a further alternative, a mixture of reactive gases may also be fed into one of the gas distribution chambers, for depositing tungsten sulfide, for example. The gas mixture may consist of tungsten hexacarbonyl W(CO)₆ and di-tert-butyl-sulfide S(C4₄H₉)₂. In one embodiment, a multilayer structure is deposited on a sapphire substrate, wherein the multilayer structure includes at least one coating or several coatings of hexagonal boron nitride (hBN) with a thickness of 5 nm, for example. Onto this coating, a graphene coating or several graphene coatings (multilayer graphene) may be deposited one on top of the other. In turn, a hBN coating, having a thickness of 3 nm for example, may be deposited on the graphene coating.

### BRIEF DESCRIPTION OF THE DRAWING

In the following text, an exemplary embodiment of the invention will be explained with reference to the accompanying drawing. In the drawing:

FIG. 1 is a schematic diagram of a CVD reactor 1 with an associated gas mixing system and

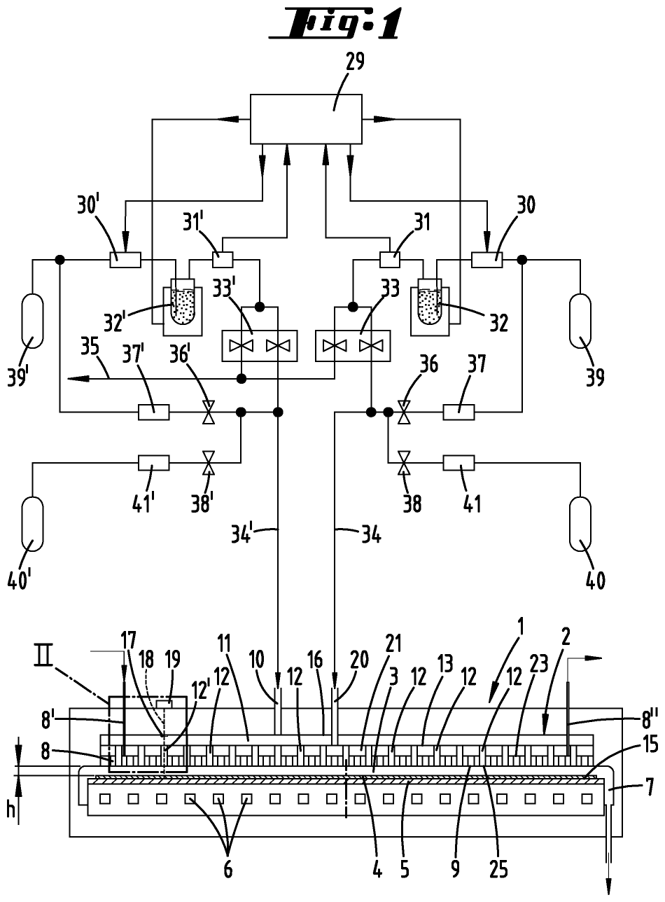

FIG. 2 shows the detail II from FIG. 1.

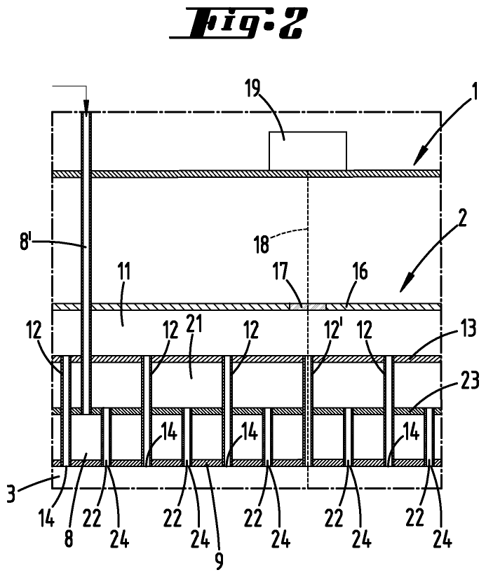

### DESCRIPTION OF THE EMBODIMENTS

The figures which a CVD reactor 1 which has a gas-gas-impermeable housing and in which a gas inlet member 2 is located. A process chamber 3, whose base forms a susceptor 5 which may be made from graphite or coated graphite is positioned below the gas inlet member 2. The susceptor 5 may be heated from below by means of a heating device 6. The heating device may be a resistance heater, an infrared heater or an inductive RF heater. A gas outlet member 7, to which a vacuum pump—not shown—is connected, extends around a susceptor 5 which has a circular footprint. The gas outlet member 7 may enclose the susceptor 5.

The upper side of the susceptor 5 facing towards the process chamber 3 has a bearing surface 15, on which a substrate 4 is supported, which substrate may consist of sapphire, silicon, a metal or similar.

The gas inlet member 2 has the form of a showerhead. Inside the gas inlet member 2 there is a cooling chamber 8 between a gas outlet plate 9 and an intermediate plate 23. A gas distribution chamber 21 above the cooling chamber 8 is located between the intermediate plate 23 and an intermediate plate 13. A further gas distribution chamber 11 is located between the intermediate plate 13 and a cover plate 16.

A supply line 20, which may be fed with gas from outside the CVD reactor, opens into the gas distribution chamber 21. A supply line 10, which may be fed with gas from outside the CVD reactor 1, opens into the gas distribution chamber 11.

The gas distribution chamber 11 is connected to the process chamber 3 via a multiplicity of pipes 12 spread in uniform arrangement over the gas outlet area 25 of the gas outlet plate 9. The pipes 12 open into a gas outlet opening 14, through which the gas fed into the gas distribution chamber 11 can flow into the process chamber 3.

The gas distribution chamber 21 is connected to the gas outlet area 25 via a multiplicity of pipes 22 so that a gas fed into the gas distribution chamber 21 can flow into the process chamber through the gas outlet openings 24 assigned to the pipes 22.

A supply line 8′ opens into the cooling chamber 8 and a coolant may be fed through the supply line into the cooling chamber 8. The coolant may flow out of the cooling chamber 8 again through discharge line 8″.

Reference numeral 19 denotes a pyrometer, with which the surface of the substrate 4 may be observed during the growth, thus enabling the surface temperature to be determined. The optical beam path 18 of the pyrometer 19 passes through a window 17 in the cover plate 16 which is transparent for the wavelength of the pyrometer 19 and though one of the pipes 12.

The gas mixing system has a control unit 29, which may be a monitoring computer. Various mass flow controllers 30, 30′; 37, 37′; 41, 41′ may be actuated with the control unit 29. The control unit 29 may also be used to adjust the temperature of a temperature bath (thermostatic bath), in which a source 32, 32′ of a liquid or solid feedstock substance in the form of bubblers 32, 32′ is located. Reference numeral 31, 31′ denotes a concentration meter, with which the concentration of the seam inside a carrier gas stream may be determined. Reference numeral 39, 39′ denotes an inert gas source or diluent gas source, which supplies an inert gas or diluent gas, for example a noble gas or a reducing gas, for example hydrogen or mixture of said gases. Reference numerals 40, 40′ denote sources of a reactive gas, for example methane or another hydrocarbon.

Reference numerals 33, 33′ denote switch valves, with which a steam that is generated in the bubblers 32, 32′ and transported by a carrier gas is routed either into a vent line 35 which bypasses the CVD reactor 1 or may be fed into one of the supply lines 10, 20 through a run line 34, 34′.

The bubblers 32, 32′ may be used to generate reactive gases. For this purpose, an inert or diluent gas from the source 39, 39′ is fed into the bubbler 32, 32′ via the mass flow controller 30, 30′. The concentration of steam in the carrier gas flow may be measured with the concentration meter 31, 31′ downstream therefrom. Before the reactive gas is fed into the gas inlet member 2, the reactive gas is routed into the vent line 35 until a gas stream has stabilized. In order to begin depositing of a two-dimensional coating, the switch valve 33, 33′ is switched so that the stabilized gas flow can be fed into one of the gas distribution chambers 11, 21 through the run line 34, 34′. In the example embodiment, two sources are shown, with which reactive gas may be generated from a powder or a liquid respectively. In embodiments that are not shown, several sources of such kind may be provided.

If no reactive gas is fed into one of the gas distribution chambers 11, 21, an inert or diluent gas from the inert or diluent gas source 39 may be fed into the gas distribution chamber 11, 21 via the valve 36, 36′ and the mass flow controller 37, 37′.

Alternatively, however, a feedstock substance available in the gas form such as methane or another hydrocarbon may also be drawn from a gas source 40, 40′ and fed into the gas distribution chamber 11, 21 via the mass flow controller 41, 41′. If available above its boiling point, borazine may be supplied from a gas source. Otherwise borazine may be made available as a gas or steam through a bubbler 32, 32′.

For depositing multilayer structures, a reactive gas or a mixture of two reactive gases is fed into one of the gas distribution chamber 11, 21 and alternating therewith an inert gas or a diluent gas is fed into the other of the gas distribution chambers 11, 21. In this way, a multilayer structure of hBN and graphene may be deposited sequentially for example by switching between a borazine flow and a methane flow. A graphene coating or multiple graphene coatings may be embedded between two hBN coatings, in particular monolayer coatings. Alternatively, however, lateral heterostructures may also be deposited, wherein various two-dimensional coatings are deposited side by side on a substrate-surface or a surface of a coating deposited previously. The coatings deposited next to each other may be connected to each other.

Alternatively, a first feedstock substance may be fed into a first of the gas distribution chambers 11, 21, and a second feedstock substance may be fed into a second of the gas distribution chambers 11, 21, or a process gas which is a mixture of two reactive gases may also be fed into one of the gas distribution chambers. For example, one of the reactive gases may be tungsten hexacarbonyl sein, which may be made available via bubbler 32, 32′. The other reactive gas may be a compound with sulfur, tellurium or selenium. Accordingly, feedstock substances may be fed either into different gas distribution chambers 11, 21 or into the same gas distribution chamber 11, 21.

The invention relates to all material pairs named in DE 10 2013 111 791 A1. To this end, the content of disclosure of that document is also incorporated in its entirety in the present filing.

The preceding notes are intended to serve as explanation of the inventions that fall within the overall scope of the application, which also each independently advance the related art at least through the following feature combinations, wherein two, several or all of said feature combinations may also be combined, namely:

A method which is characterized in that the gas inlet member 2 has at least two gas distribution chambers 11, 21 which are separate from each other, and which are each fed by one supply line 10, 20 with gases or gas mixtures that differ from each other and simultaneously exit the gas outlet openings 14, 24, which are different from each other and each assigned to one of the gas distribution chambers 11, 21.

A use, characterized in that the gas inlet member 2 has at least two gas distribution chambers 11, 21 that are separate from each other and each fed via a supply line 10, 20 with gases or gas mixtures that differ from each other and simultaneously exit the gas outlet openings 14, 24, which are different from each other and each assigned to one of the gas distribution chambers 11, 21.

A method or use, characterized in that an inert gas or a diluent gas is fed into a first 11 of the gas distribution chambers 11, 21, and a reactive gas or a gas mixture of a gas containing elements from which the two-dimensional coating is constructed and is fed into a second 21 of the gas distribution chambers 11, 21, which reactive gas is decomposed in the process chamber 3, for example pyrolytically, wherein the decomposition products form a two-dimensional coating, or that different reactive gases are fed into the gas distribution chamber 11, 21, and react with each other chemically in the process chamber 3, forming a two-dimensional coating.

A method or use, characterized in that on a first two-dimensional coating deposited in a first step, during the deposit of which an inert gas or a diluent gas is fed through the first gas distribution chamber 11 and 20 and the gas outlet openings 14 assigned thereto, and a first reactive gas or a gas mixture, particularly containing gases with the elements of the two-dimensional coating, is fed through the second gas distribution chamber 21 and den gas outlet openings 24 assigned thereto, into the process chamber, in a second step a second two-dimensional coating is deposited, during the deposit of which a second reactive gas, different from the first reactive gas, is fed in through the first gas distribution chamber 1 and the gas outlet openings 14 assigned thereto, and an inert gas or a diluent gas is fed into the process chamber through the second gas distribution chamber 21 and the gas outlet openings 24 assigned thereto, wherein it is provided in particular that the two steps are performed once or multiple times.

A method or use, characterized in that two-dimensional coatings that differ from each other are deposited one on top of the other in multiple consecutive steps, wherein the reactive gases used therefor are fed into different gas distribution chambers 11, 21 in particular alternately.

An apparatus, characterized in that the gas inlet member 2 has two gas distribution chambers 11, 21 which are separate from each other, each having a supply line 10, 20, wherein each of the two supply lines 10, 20 may be flow-connected optionally to an inert gas source, a diluent gas source or one of the reactive gas sources.

A method, a use or an apparatus, characterized by a switching apparatus 33, 33′; 36, 36′; 38, 38′, with which the inert gas source or diluent gas source 39, 39′ or one of the reactive gas sources 32, 32′; 40, 40′ may be brought into a flow connection optionally or alternately with a gas distribution chamber 11, 21.

A method, a use or an apparatus, characterized in that the reactive gas sources 32, 32′ can be connected optionally or alternately to a vent line 35, via which the reactive gases bypass or are routed past the process chamber 3, or to a run line 34, 34′, with which the reactive gases can be introduced into the process chamber 3.

A method, a use or an apparatus, characterized in that the gas inlet member 2 is a showerhead with a gas outlet area 25 in which the gas outlet openings 14, 24 are arranged, in which two gas distribution chambers 11, 21 separated from each other by an intermediate plate 13 are arranged, each being flow-connected via pipes 12, 12′, 22 to the gas outlet openings 14, 24 distributed evenly over the gas outlet area 25, and/or that the material of the two-dimensional coating is graphene, hBN, or a transition metal dichalcogenide, in particular MoS₂, WS₂, MoSe₂ or WSe₂, and/or that the reactive gas or a reactive gas mixture contains a hydrocarbon compound, for example methane or a boron compound, for example borazine, and/or that a first reactive gas is an element of a transition metal and particular a molybdenum compound or a tungsten, and that a second reactive gas contains an element of main group VI and in particular is a sulfur compound, for example di-tert-butyl sulfide, a selenium compound or a tellurium compound, and/or that the inert gas is a noble gas, for example argon, and that the diluent gas is a reducing gas, for example hydrogen.

All disclosed features are (individually but also in combination with each other) essential to the invention. The contents of disclosure of the associated/accompanying priority documents (copy and previous application) are herewith also incorporated in the disclosure of the application in their entirety, also for the purpose of including the features of said documents in claims of the present application. With their features, the subordinate claims characterize stand-alone inventive advances of the related art even without the features of a referenced claim, in particular with a view to submitting divisional applications on the basis of said claims. The invention defined in each claim may also include one or more of the features specified in the preceding description, in particular such that are denoted with reference numerals and/or are referenced in the list of reference numerals. The invention also relates to design variants in which individual features defined in the preceding description have not been realized, particularly if they are evidently not essential in order to fulfil the respective intended purpose or if they can be replaced with other technically equivalent means.

### LIST OF REFERENCE NUMERALS

1 CVD reactor
2 Gas inlet member
3 Process chamber
4 Substrate
5 Susceptor
6 Heating device
7 Gas outlet member
8 Cooling chamber
8′ Supply line
8″ Discharge line
9 Gas outlet plate
10 Supply line
11 Gas distribution chamber
12 Pipe
12′ Pipe
13 Intermediate plate
14 Gas outlet opening
15 Bearing surface
16 Cover plate
17 Window
18 Beam path
19 Optical device, pyrometer
20 Supply line
21 Gas distribution chamber
23 Intermediate plate
24 Gas outlet opening
25 Gas outlet area
29 Control unit
30 Mass flow controller
30′ Mass flow controller
31 Concentration meter
31′ Concentration meter
32 Bubbler
32′ Bubbler
33 Switch valve
33′ Switch valve
34 Run line
34′ Run line
35 Vent line
37 Mass flow controller
37′ Mass flow controller
39 Inert gas source
39′ Inert gas source
40 Reactive gas source
40′ Reactive gas source
41 Mass flow controller
41′ Mass flow controller
T_{P} Process temperature

1. A method for depositing a first and second coating on a substrate (4) in a chemical vapor deposition (CVD) reactor (1) that includes a process chamber (3) and a gas inlet member (2), the gas inlet member (2) including a first gas distribution chamber (11) and a second gas distribution chamber (21) separated from the first gas distribution chamber (11), the method comprising:
(i) feeding an inert gas or a diluent gas into the process chamber (3) through the first gas distribution chamber (11) while feeding a first reactive gas or a first gas mixture into the process chamber (3) through the second gas distribution chamber (21);
(ii) heating the substrate (4) to a process temperature so as to form the first coating on a surface of the substrate (4) from decomposition products of the first reactive gas or the first gas mixture;
(iii) feeding the inert gas or the diluent gas into the process chamber (3) through the second gas distribution chamber (21) while feeding a second reactive gas or a second gas mixture into the process chamber (3) through the first gas distribution chamber (11); and
(iv) heating the substrate (4) to the process temperature so as to form the second coating on or adjacent to the first coating from decomposition products of the second reactive gas or the second gas mixture.

2. (canceled)

3. The method of claim 1, wherein the first reactive gas is different from the second reactive gas.

4. The method of claim 1, further comprising repeating steps (i)-(iv).

5. The method of claim 1, wherein the first coating is different from the second coating.

6. The method of claim 1, wherein the second coating is deposited on the first coating.

7. The method of claim 1, wherein the first reactive gas is different from the second reactive gas, and the first gas mixture is different from the second gas mixture.

8. The method of claim 1, further comprising:
flowing the inert gas or the diluent gas into the first or the second gas distribution chamber through a switching apparatus (33, 33′; 37, 37′; 38, 38′);
flowing the first reactive gas or the first gas mixture into the first or the second gas distribution chamber through the switching apparatus (33, 33′; 37, 37′; 38, 38′); and
flowing the second reactive gas or the second gas mixture into the first or the second gas distribution chamber through the switching apparatus (31, 33′; 37, 37′; 38, 38′).

9. The method of claim 1, further comprising flowing the first or second reactive gas through a vent line (35) instead of through a run line (34, 34′) which is fluidly connected to the process chamber (3).

10. The method of claim 1,
wherein the first gas distribution chamber (11) is fluidly connected to the process chamber (3) via a first plurality of pipes (12),
wherein the second gas distribution chamber (21) is fluidly connected to the process chamber (3) via a second plurality of pipes (22),
wherein the first gas distribution chamber (11) is separated from the second gas distribution chamber (21) by an intermediate plate (13),
wherein the first plurality of pipes (12) open into the process chamber (3) via a first plurality of gas outlet openings (14) that are uniformly distributed over a gas outlet surface (25) of the gas inlet member (2), and
wherein the second plurality of pipes (22) open into the process chamber (3) via a second plurality of gas outlet openings (24) that are uniformly distributed over the gas outlet surface (25) of the gas inlet member (2).

11. The method of claim 1, wherein the first and second coatings comprise at least one of graphene, hBN or a transition metal dichalcogenide.

12. The method of claim 1, wherein the first reactive gas contains at least one of a hydrocarbon compound or borazine.

13. The method of claim 1, wherein the first reactive gas contains a compound of a transition metal.

14. The method of claim 1, wherein the second reactive gas contains an element from main group VI, and the inert gas or diluent gas is a noble gas.

15. (canceled)

16. The method of claim 1, wherein the first and second coatings comprise at least one of MoS₂, WS₂, MoSe₂ or WSe₂.
